(19) United States
(12) Patent Application Publication
(10) Pub. No.: US 2017/0128962 A1
(43) Pub. Date: May 11, 2017

(54) NOZZLE STANDBY DEVICE AND SUBSTRATE TREATING APPARATUS

(71) Applicant: SCREEN Holdings Co., Ltd., Kyoto (JP)

(72) Inventors: Masahito KASHIYAMA, Kyoto-shi (JP); Yasuo TAKAHASHI, Kyoto-shi (JP); Kota KABUNE, Kyoto-shi (JP); Shoji KIRITA, Kyoto-shi (JP); Toru MOMMA, Kyoto-shi (JP)

(21) Appl. No.: 15/344,933

(22) Filed: Nov. 7, 2016

(30) Foreign Application Priority Data
Nov. 10, 2015 (JP) 2015-220406

(51) Int. Cl. B05B 3/02; B05B 12/02

(52) U.S. Cl. CPC B05B 3/02; B05B 12/02

(57) ABSTRACT

A first feed section supplies a solvent from a first discharge opening formed in a side surface of a nozzle receiving portion. A cylindrical drain flow path is attached to a bottom surface of the nozzle receiving portion. The drain flow path drains at least a coating solution dispensed from a nozzle placed in the nozzle receiving portion. The drain flow path has a second feed section for adjusting a drain flow rate of the solvent flowing from the nozzle receiving portion and passing through the drain flow path. With the second feed section adjusting the drain flow rate when the solvent flows through the drain flow path, although an inside diameter of the drain flow path is set larger than a diameter of a nozzle dispenser opening, the solvent can be collected stably in the nozzle receiving portion, whereby the solvent can easily be sucked into a nozzle tip.

### CROSS-REFERENCE TO RELATED APPLICATIONS

This application claims priority to Japanese Patent Application No. 2015-220406 filed Nov. 10, 2015 the subject matter of which is incorporated herein by reference in entirety.

### TECHNICAL FIELD

This invention relates to a nozzle standby device for holding on standby nozzles which dispense a treating solution to substrates such as semiconductor substrates, glass substrates for liquid crystal displays, glass substrate for photomasks, substrates for optical disks and so on, and also relates to a substrate treating apparatus having such nozzle standby device.

### BACKGROUND ART

Substrate treating apparatus include a coating apparatus, for example. The coating apparatus has a holding and spinning unit for holding and spinning each substrate, and a plurality of nozzles which dispense a coating solution. Each of the nozzles stands by in a standby pot. A nozzle moving mechanism (robot) grips one of the nozzles standing by in the standby pot, and moves the gripped nozzle to a position above the substrate. Then, the coating apparatus applies a coating solution from the nozzle to the substrate. After the coating step, the nozzle is returned to the standby pot by the nozzle moving mechanism.

FIG. 1 is a view showing a conventional standby pot. Standby pot 131 has a dispense portion 135 and a solvent sucking portion 136 (see Japanese Unexamined Patent Publications No. 2011-233907 and No. 2010-103131, for example). The dispense portion 135 performs dummy dispensation or predispensation (hereinafter called “dummy dispensation” as representative), and puts a nozzle 103 on standby. On the other hand, the solvent sucking portion 136 sucks a solvent into the tip of the nozzle 103. Where the coating apparatus has ten nozzles 103, as shown in FIG. 2, the standby pot 131 is constructed to have an array of ten sets each including one dispense portion 135 and one solvent sucking portion 136.

The standby pot 131 of FIGS. 1 and 2 has the following drawback. It is necessary to move the nozzle 103 to the dispense portion 135 at the time of dummy dispensation, or to the solvent sucking portion 136 at the time of sucking in the solvent. Further, when the nozzle 103 is moved to the solvent sucking portion 136, the above nozzle moving mechanism grips the nozzle 103 which performs the solvent suction. During this operation, therefore, the nozzle moving mechanism cannot grip a different nozzle 103 to apply the coating solution to a substrate.

On the other hand, Japanese Unexamined Patent Publication No. 2012-235132 has proposed a standby unit which carries out dummy dispensation and solvent suction in one cleaning chamber, thereby to eliminate the need for nozzle movements to perform each operation. That is, the standby unit in Japanese Unexamined Patent Publication No. 2012-235132 provides a cleaning chamber having a cylindrical portion, and a funnel portion communicating with a lower end of the cylindrical portion and shaped to taper downward. A communication channel is further provided at a lower end of the funnel portion of the cleaning chamber, and a resist solution and a solvent can be drained through the communication channel. A nozzle placed in the cleaning chamber carries out dummy dispensation, and in the same cleaning chamber, sucks in the solvent to prevent drying of the resist solution, thereby forming a solvent layer inside the tip of the nozzle.

### SUMMARY OF INVENTION

### Technical Problem

However, these conventional devices have the following problems. As in FIG. 2, the conventional standby pot 131 includes one switch valve V for supplying and stopping the supply of the solvent to the ten solvent sucking portions 136. The solvent is therefore supplied to all the solvent sucking portions 136. That is, in order to carry out the solvent suction for one nozzle 103, the solvent is supplied also to the other nine solvent sucking portions 136. This gives rise to a problem of increasing consumption of the solvent. Further, since it is necessary to supply the solvent evenly to all the solvent sucking portions 136, the construction of flow paths formed in the standby pot 131 becomes complicated in order to supply the solvent. Simplification of the construction is desired.

At the time of solvent suction, outer peripheries at the tip of the nozzle are dipped in the solvent, and are therefore additionally cleaned. But when these parts are badly stained, the stains will remain on the nozzle. It is therefore desired to eliminate such cleaning omissions.

The stains on the nozzle can clog up a solvent drain flow path 138 of the solvent sucking portion 136 shown in FIG. 1. On the other hand, where the dummy dispensation and solvent suction are carried out in the same location as disclosed in Japanese Unexamined Patent Publication No. 2012-235132, the drain flow path is set to have a large inside diameter for the dummy dispensation. This lowers the possibility of the drain flow path getting clogged with the stains. However, there arises a different problem of making it difficult to collect the solvent to suck in.

In this connection, Japanese Unexamined Patent Publication No. 2012-235132 provides two inflow paths (a lower inflow path and an upper inflow path) for the cleaning chamber. The lower inflow path is provided in a slope of the funnel portion of the cleaning chamber, while the upper inflow path is provided in an inner circumferential surface of the cylindrical portion above the funnel portion. At the time of solvent suction, the solvent is supplied from the two inflow paths to collect the solvent in the cleaning chamber. However, with the lower inflow path provided in the slope of the funnel portion, the solvent whirls along the slope of the funnel portion, and the solvent also rises along the slope of the funnel portion. The solvent, whirling and rising, can flow over. Even if the solvent does not flow over, there arises a problem that the solvent collecting in the cleaning chamber can easily become unstable, which makes it difficult to suck the solvent into the tip of the nozzle.

This invention has been made having regard to the state of the art noted above, and its object is to provide a nozzle standby device and a substrate treating apparatus which can curb consumption of a nozzle cleaning liquid, and can easily suck the nozzle cleaning liquid into the tip of a nozzle.

### Solution to Problem

To fulfill the above object, this invention provides the following construction.

A nozzle standby device for holding a nozzle on standby, according to this invention, comprises a nozzle receiving portion having an opening in an upper surface thereof for receiving the nozzle through the opening, the nozzle receiving portion being formed to taper from the opening toward a bottom surface thereof; a cylindrical drain flow path attached to the bottom surface of the nozzle receiving portion for draining at least a treating liquid dispensed from the nozzle placed in the nozzle receiving portion, the drain flow path having an inside diameter larger than a diameter of a nozzle dispenser opening of the nozzle; a first feed section having a first discharge opening formed in a side surface of the nozzle receiving portion for supplying a nozzle cleaning liquid from the first discharge opening; and a drain flow rate adjuster provided for the drain flow path for adjusting a drain flow rate of the nozzle cleaning liquid flowing from the nozzle receiving portion and passing through the drain flow path.

According to the nozzle standby device of this invention, the nozzle receiving portion, which receives the nozzle through the opening formed in the upper surface thereof, is formed to taper from the opening toward the bottom surface. The first feed section has the first discharge opening formed in the side surface inside the nozzle receiving portion, and supplies the nozzle cleaning liquid from the first discharge opening. The nozzle receiving portion has the cylindrical drain flow path attached to the bottom surface thereof. The drain flow path drains at least the treating liquid dispensed from the nozzle placed in the nozzle receiving portion. Since the drain flow path has an inside diameter set to be larger than the diameter of the nozzle dispenser opening of the nozzle, the treating liquid dispensed from the nozzle is smoothly drained from the drain flow path. As a result, the treating liquid does not easily adhere to the nozzle receiving portion. On the other hand, the drain flow path is provided with the drain flow rate adjuster which adjusts the drain flow rate of the nozzle cleaning liquid flowing from the nozzle receiving portion and passing through the drain flow path. With the drain flow rate adjuster adjusting the drain flow rate when the nozzle cleaning liquid flows through the drain flow path, although the inside diameter of the drain flow path is set larger than the diameter of the nozzle dispenser opening, the nozzle cleaning liquid can be collected stably in the nozzle receiving portion, whereby the nozzle cleaning liquid can easily be sucked into the tip of the nozzle.

In the above nozzle standby device, it is preferred that the drain flow rate adjuster comprises a second feed section having a second discharge opening formed in a side surface inside the drain flow path for supplying the nozzle cleaning liquid from the second discharge opening into the drain flow path to be away from a central axis of the drain flow path.

Assume, for example, that the second discharge opening is formed in the slope inside the nozzle receiving portion formed to taper from the opening in the upper surface toward the bottom surface. In this case, the nozzle cleaning liquid flows in a whirl upward along the slope. Consequently, the nozzle cleaning liquid can overflow the nozzle receiving portion. The nozzle cleaning liquid becomes unable to be collected stably in the nozzle receiving portion. Since the nozzle cleaning liquid is supplied from the second discharge opening to be away from the central axis of the cylindrical drain flow path, the nozzle cleaning liquid flows in a whirl in the drain flow path. However, since the drain flow path is cylindrical, the nozzle cleaning liquid will not rise along its inner surface. With the nozzle cleaning liquid supplied from the second discharge opening and flowing in a whirl in the drain flow path, the cleaning liquid supplied from the first discharge opening to the nozzle receiving portion is prevented from flowing through the drain flow path. As a result, the nozzle cleaning liquid can be collected stably in the nozzle receiving portion.

In the above nozzle standby device, it is preferred that the first discharge opening is in form of a ring-shaped slit directed inward. Consequently, the solvent can be supplied evenly toward the entire circumference of the nozzle placed in the nozzle receiving portion, thereby to reduce nozzle cleaning omissions.

In the above nozzle standby device, it is preferred that the first feed section has a ring-shaped flat horizontal flow path, the horizontal flow path having an opening at an inner circumference end thereof acting as the first discharge opening. In the horizontal flow path, the nozzle cleaning liquid flows from the outer circumference end toward the first discharge opening at the inner circumference end. At this time, since the horizontal flow path is a ring-shaped flat flow path, the horizontal flow path is contracted progressively from the outer circumference end toward the inner circumference end. Consequently, it becomes difficult for the nozzle cleaning liquid to flow toward the first discharge opening, and thus the nozzle cleaning liquid flows round in the circumferential direction along the horizontal flow path. The nozzle cleaning liquid can therefore be supplied evenly from the first discharge opening toward the nozzle. Since the first discharge opening is slit-shaped, the cleaning liquid can be supplied in a vigorous state to the nozzle.

In the above nozzle standby device, it is preferred that the first feed section further includes a cleaning liquid flow path for sending the nozzle cleaning liquid to the first discharge opening, the cleaning liquid flow path being formed in a block in which the nozzle receiving portion is formed, and a switch valve having a valving element which takes opening and closing action for opening and closing the cleaning liquid flow path; the cleaning liquid flow path includes a hole interposed therein to communicate with the cleaning liquid flow path; the hole includes a valve seat formed therein for shutting off the cleaning liquid flow path with the valving element, the switch valve being disposed in the hole to have the valving element movable forward and backward; and the switch valve cuts off circulation of the cleaning liquid by settling the valving element on the valve seat in the hole, and circulating the cleaning liquid by separating the valving element from the valve seat in the hole.

In the above construction, the hole interposed in the solvent flow path has the valve seat formed therein and accommodates the switch valve. The valve seat is a component separate from the switch valve, and is formed in the hole formed in the same body block in which the nozzle receiving portion is formed. Therefore, where the nozzle standby device has a plurality of nozzle receiving portions, the construction can be made more compact than an ordinary switch valve having a valving element and a valve seat.

It is preferred that the above nozzle standby device comprises a plurality of nozzle receiving portions; wherein each of the nozzle receiving portions includes at least the drain flow path, the first feed section including the switch valve, and the drain flow rate adjuster. With this construction, a plurality of nozzles can be put on standby, and the above-noted effects are acquired with the plurality of nozzle receiving portions. For example, with the switch valve provided for each of the nozzle receiving portions, the construction of the nozzle standby device having the switch valves can be made compact. The switch valve provided for each nozzle receiving portion can selectively supply the cleaning liquid. Consumption of the cleaning liquid can be held down since the cleaning liquid is supplied only to the nozzle receiving portions needing to be cleaned among the plurality of nozzle receiving portions. The complexity of the construction of the cleaning liquid flow paths can also be lessened.

In the above nozzle standby device, it is preferred that the nozzle receiving portion has a lower part thereof formed in shape of an inverted cone. Assume, for example, the bottom surface in the nozzle receiving portion is in the form of a concave hemisphere surface. In this case, when a resist solution as the treating liquid, for example, remains in the hemisphere surface after cleaning of the nozzle, the resist solution tends to remain without being removed even if a solvent as the nozzle cleaning liquid, for example, is supplied. With the lower part of the nozzle receiving portion formed in the shape of an inverted cone, even if it is tainted with the resist solution, the resist solution remnant can be inhibited. This facilitates maintenance of the cleanliness of the interior of the nozzle receiving portion.

In another aspect of this invention, a substrate treating apparatus comprises a nozzle for dispensing a treating liquid to a substrate; and a nozzle standby device for holding the nozzle on standby; wherein the nozzle standby device includes a nozzle receiving portion having an opening in an upper surface thereof for receiving the nozzle through the opening, the nozzle receiving portion being formed to taper from the opening toward a bottom surface thereof; a cylindrical drain flow path attached to the bottom surface of the nozzle receiving portion for draining at least a treating liquid dispensed from the nozzle placed in the nozzle receiving portion, the drain flow path having an inside diameter larger than a diameter of a nozzle dispenser opening of the nozzle; a first feed section having a first discharge opening formed in a side surface of the nozzle receiving portion for supplying a nozzle cleaning liquid from the first discharge opening; and a drain flow rate adjuster provided for the drain flow path for adjusting a drain flow rate of the nozzle cleaning liquid flowing from the nozzle receiving portion and passing through the drain flow path.

The substrate treating apparatus according to this invention has the nozzle for dispensing the treating liquid to the substrate, and the nozzle standby device for holding the nozzle on standby. In the nozzle standby device, the nozzle receiving portion, which receives the nozzle through the opening formed in the upper surface thereof, is formed to taper from the opening toward the bottom surface. The first feed section has the first discharge opening formed in the side surface inside the nozzle receiving portion, and supplies the nozzle cleaning from the first discharge opening. The nozzle receiving portion has the cylindrical drain flow path attached to the bottom surface thereof. The drain flow path drains at least the treating liquid dispensed from the nozzle placed in the nozzle receiving portion. Since the drain flow path has an inside diameter set to be larger than the diameter of the nozzle dispenser opening of the nozzle, the treating liquid dispensed from the nozzle is smoothly drained from the drain flow path. As a result, the treating liquid does not easily adhere to the nozzle receiving portion. On the other hand, the drain flow path is provided with the drain flow rate adjuster which adjusts the drain flow rate of the nozzle cleaning liquid flowing from the nozzle receiving portion and passing through the drain flow path. With the drain flow rate adjuster adjusting the drain flow rate when the nozzle cleaning liquid flows through the drain flow path, although the inside diameter of the drain flow path is set larger than the diameter of the nozzle dispenser opening, the nozzle cleaning liquid can be collected stably in the nozzle receiving portion, whereby the nozzle cleaning liquid can easily be sucked into the tip of the nozzle.

### Advantageous Effects of Invention

According to the nozzle standby device and substrate treating apparatus of this invention, the nozzle receiving portion, which receives the nozzle through the opening formed in the upper surface thereof, is formed to taper from the opening toward the bottom surface. The first feed section has the first discharge opening formed in the side surface inside the nozzle receiving portion, and supplies the nozzle cleaning from the first discharge opening. The nozzle receiving portion has the cylindrical drain flow path attached to the bottom surface thereof. The drain flow path drains at least the treating liquid dispensed from the nozzle placed in the nozzle receiving portion. Since the drain flow path has an inside diameter set to be larger than the diameter of the nozzle dispenser opening of the nozzle, the treating liquid dispensed from the nozzle is smoothly drained from the drain flow path. As a result, the treating liquid does not easily adhere to the nozzle receiving portion. On the other hand, the drain flow path is provided with the drain flow rate adjuster which adjusts the drain flow rate of the nozzle cleaning liquid flowing from the nozzle receiving portion and passing through the drain flow path. With the drain flow rate adjuster adjusting the drain flow rate when the nozzle cleaning liquid flows through the drain flow path, although the inside diameter of the drain flow path is set larger than the diameter of the nozzle dispenser opening, the nozzle cleaning liquid can be collected stably in the nozzle receiving portion, whereby the nozzle cleaning liquid can easily be sucked into the tip of the nozzle.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a view in vertical section showing a construction of a conventional standby pot;

FIG. 2 is a view showing the conventional standby pot and a solvent supply system;

FIG. 3 is a schematic view of an outline of a coating apparatus according to this invention;

FIG. 4 is a plan view of the coating apparatus according to this invention;

FIG. 5 is a view in vertical section showing a construction of a standby pot;

FIG. 6 is a view in vertical section of a nozzle receiving portion, a first discharge opening and a cylindrical flow path seen from an obliquely upward direction;

FIG. 7 is a cross section showing a drain flow path and a second discharge opening;

FIG. 8 is a view showing a solvent supply system;

FIG. 9A is a view illustrating dummy dispensation;

FIG. 9B is a view illustrating operation for supplying a solvent from the first discharge opening and second discharge opening;

FIG. 9C is a plan view illustrating operation for supplying the solvent from the first discharge opening;

FIG. 9D is a view illustrating operation for sucking the solvent into a nozzle;

FIG. 9E is a view showing a state of the nozzle after sucking in the solvent;

FIG. 10 is a view in vertical section of a standby pot according to a modification;

FIG. 11A is a cross section showing a pinch valve and a drain pipe of FIG. 10;

FIG. 11B is a cross section showing a diaphragm valve and a drain flow path according to a further modification of what is shown in FIG. 11A, and

FIG. 12 is a perspective view showing a standby pot according to another modification.

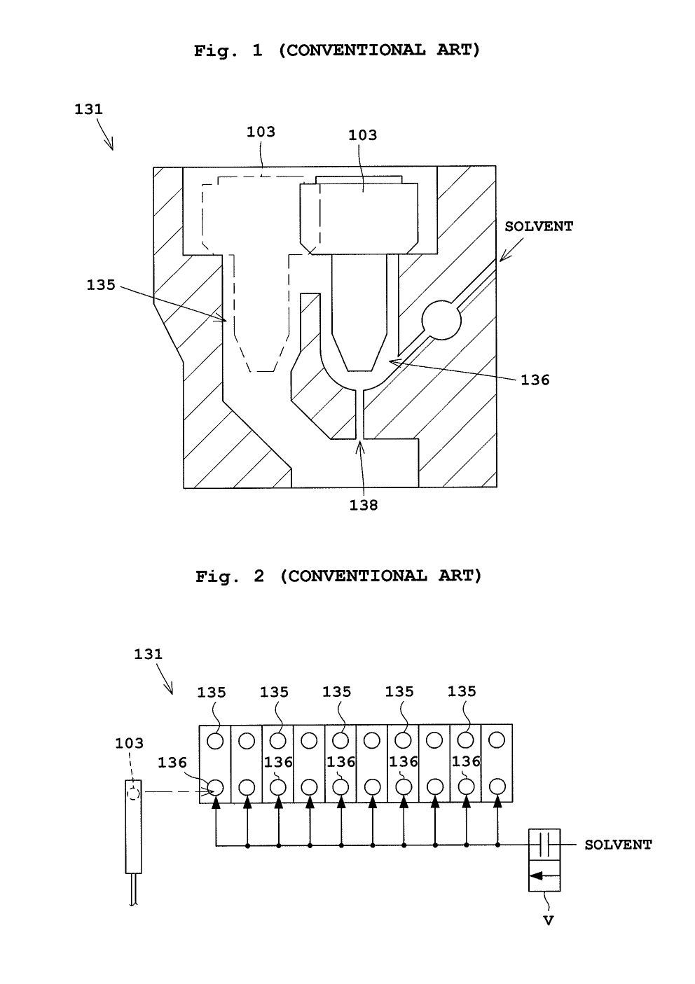

### EMBODIMENT

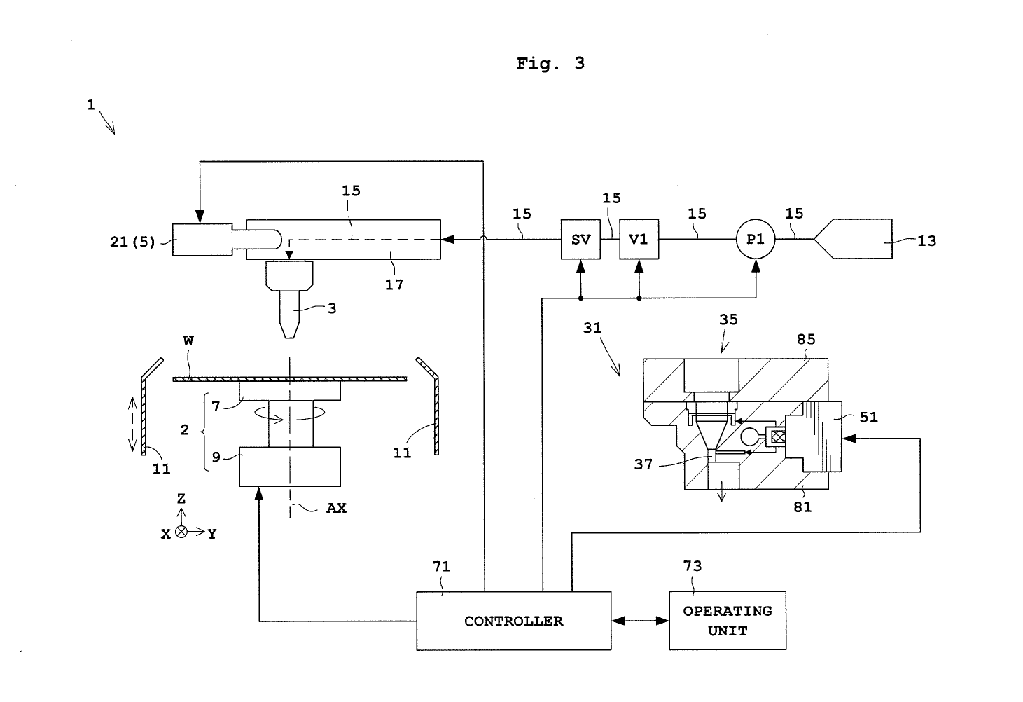

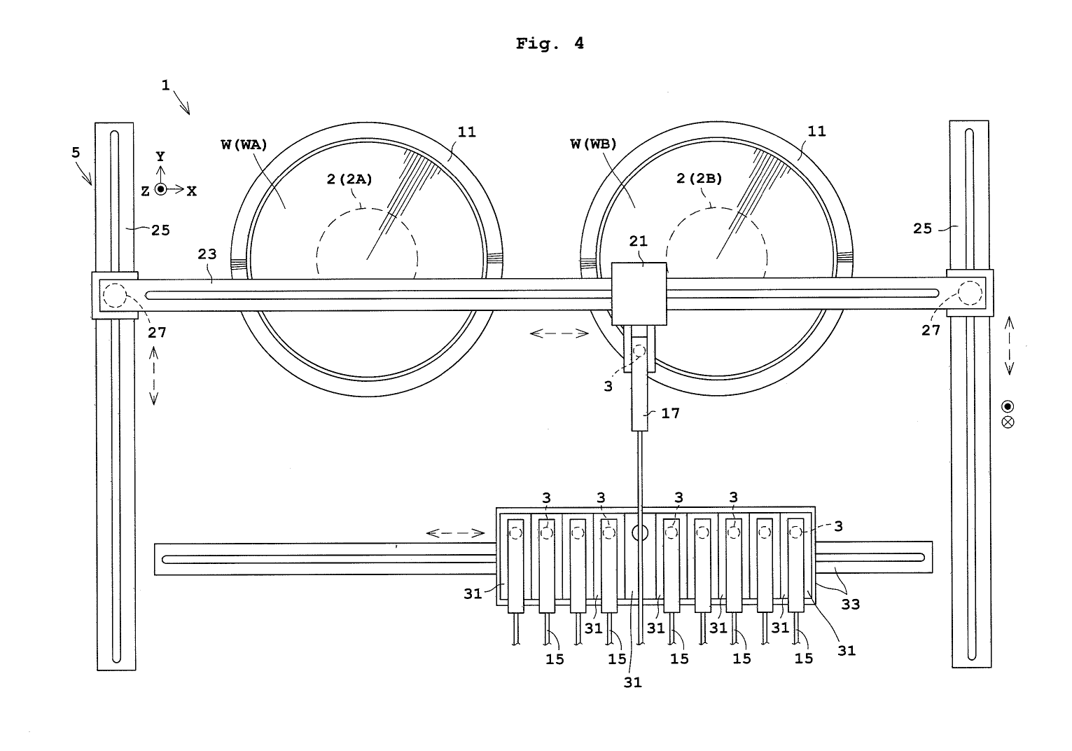

An embodiment of this invention will described hereinafter with reference to the drawings. FIG. 3 is a schematic view of an outline of a coating apparatus according to this invention. FIG. 4 is a plan view of the coating apparatus according to this invention.

<Construction of Coating Apparatus 1>

Reference is made to FIGS. 3 and 4. A coating apparatus 1 includes holding and spinning units 2 each for holding and spinning a wafer W in a substantially horizontal position, nozzles 3 for dispensing a coating solution to the wafers W, and a nozzle moving mechanism 5 for moving the nozzles 3. The coating solution is for forming film on the wafers W. The coating solution used here is a photoresist solution, SOG (Spin on glass coating) solution, SOD (Spin on dielectric coating) solution, polyimide resin solution, or the like. The coating solution corresponds to the treating liquid in this invention.

The holding and spinning units 2 each include a spin chuck 7 for holding the back surface of the wafer W by vacuum suction, for example, and a spin driver 9 in the form of a motor, for example, which rotates the spin chuck 7 about a substantially vertical rotation axis AX. A vertically movable cup 11 is disposed around the holding and spinning unit 2 to surround laterally of the wafer W. A plurality of (e.g. two) such holding and spinning units 2 are provided as shown in FIG. 4.

The coating solution is supplied to each nozzle 3 through coating solution piping 15 from a coating solution supply source 13. The coating solution piping 15 has a suckback valve SV, a switch valve V1 and a pump P1 arranged in intermediate positions thereof. The switch valve V1 supplies and stops supply of the coating solution. The suckback valve SV is operable in combination with operation of the switch valve V1 to suck the coating solution and other substances from the nozzle 3, and pushes out the coating solution and other substances sucked. The pump P1 feeds the coating solution to the nozzle 3. The nozzle 3 is attachably and detachably supported by a support block 17.

There are provided, for example, ten (a plurality of) nozzles 3 as shown in FIG. 4. Each of the nozzles 3 has the above-noted coating solution supply source 13, coating solution piping 15, switch valve V1, suckback valve SV and pump P1. The number of nozzles 3 may be other than ten.

The nozzle moving mechanism 5 grips any one of the ten nozzles 3, and moves the gripped nozzle 3, for example, from a standby pot 31 described hereinafter to a position above the wafer W. As shown in FIG. 4, the nozzle moving mechanism 5 includes a gripper 21 for gripping the nozzles 3, and a first horizontal movement portion 23 for horizontally moving the gripper 21 in a first direction (X-direction). The nozzle moving mechanism 5 further includes second horizontal movement portions 25 for horizontally moving the gripper 21 in a second direction (Y-direction) substantially perpendicular to the first direction, and vertical movement portions 27 for moving the gripper 21 in a vertical direction (Z-direction).

In this embodiment, the gripper 21 is supported by the first horizontal movement portion 23 to be movable in the first direction. The first horizontal movement portion 23 is supported by the vertical movement portions 27 to be vertically movable. The vertical movement portions 27 are supported by the second horizontal movement portions 25 to be movable in the second direction. The gripper 21, first horizontal movement portion 23, second horizontal movement portions 25 and vertical movement portions 27 are formed of motors and guides (e.g. guide rails) or air cylinders and guides, and so on. The nozzle moving mechanism 5 may include a horizontal articulated arm instead of at least either the first horizontal movement portion 23 or the second horizontal movement portions 25.

Each nozzle 3, when not in use, is put on standby in the standby pot 31. The standby pot 31 is constructed to dispense the coating solution from the nozzle 3 (dummy dispensation) or suck a solvent into the nozzle 3. Ten standby pots 31, for example, are provided, which are the same in number as the nozzles 3. The ten standby pots 31 are mounted on a standby pot moving mechanism 33 as shown in FIG. 4. The ten standby pots 31 as a whole are constructed movable along the X-direction in which the two holding and spinning units 2 are arranged. The standby pot moving mechanism 33 is formed of a support block, a motor, a guide, and so on. The standby pots 31 constitute the nozzle standby device in this invention.

[Standby Pots 31]

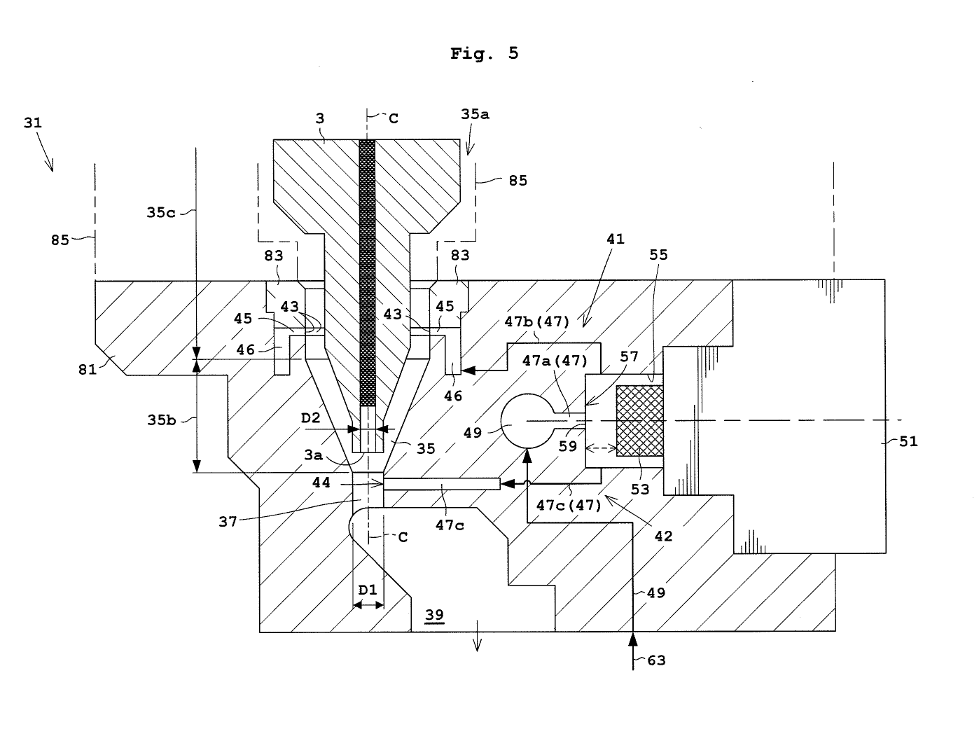

A specific construction of each standby pot 31 will be described. A solvent such as thinner, for example, is supplied as nozzle cleaning liquid to the standby pot 31. First, the construction of each standby pot 31 will be described with reference to FIG. 5.

The standby pot 31, as shown in FIG. 5, includes a nozzle receiving portion 35 for receiving the nozzle 3, a substantially cylindrical drain flow path 37 attached to a bottom surface in the nozzle receiving portion 35, a waste liquid collecting portion 39 which is a flow path for collecting waste liquids through the drain flow path 37.

The nozzle receiving portion 35 has an opening 35a in an upper surface thereof, and the nozzle 3 is received and taken out through the opening 35a. The nozzle receiving portion 35 is formed to taper from the opening 35 toward the bottom surface. For example, the nozzle receiving portion 35 has a lower part 35b thereof corresponding to an outer circumference at the tip of the nozzle 3 received, which the lower part 35b is formed in the shape of an inverted cone, and an upper part 35c formed substantially cylindrical. The nozzle receiving portion 35 is formed to have an approximately circular cross-sectional shape including circular, elliptical and polygonal shapes.

On the other hand, the drain flow path 37 drains off the coating solution dispensed from the nozzle 3 placed in the nozzle receiving portion 35 and the solvent supplied to the nozzle receiving portion 35. The drain flow path 37 has an inside diameter D1 thereof larger than a diameter D2 of a nozzle dispenser opening 3a of the nozzle 3. The drain flow path 37 is formed cylindrical. The cylinder is a right circular cylinder. The cylinder has the same flow path cross-sectional area from bottom surface to upper surface, and its side surface does not incline like an inverted cone or inverted truncated cone. The circle of the cylinder may be an approximately circular shape including circular, elliptical and polygonal shapes. The substantially circular cross sections of the drain flow path 37 and nozzle receiving portion 35 have the same central axis C (coaxial).

The standby pot 31 includes a first feed section 41 and a second feed section 42. The first feed section 41 has a first discharge opening 43 formed in the side surface inside the nozzle receiving portion 35, and the solvent is supplied to the nozzle receiving portion 35 from this first discharge opening 43. The first discharge opening 43 supplies the solvent toward an outer circumferential surface of the nozzle 3. On the other hand, the second feed section 42 has a second discharge opening 44 formed in the side surface inside the drain flow path 37. The second feed section 42 produces swirling currents in the drain flow path 37 by supplying the solvent from this second discharge opening 44 to the drain flow path 37. The second feed section 42, with these swirling currents, adjusts the distributivity of the drain flow path 37, that is the drain flow rate of the solvent supplied into the nozzle receiving portion 35. The second feed section 42 corresponds to the drain flow rate adjuster in this invention.

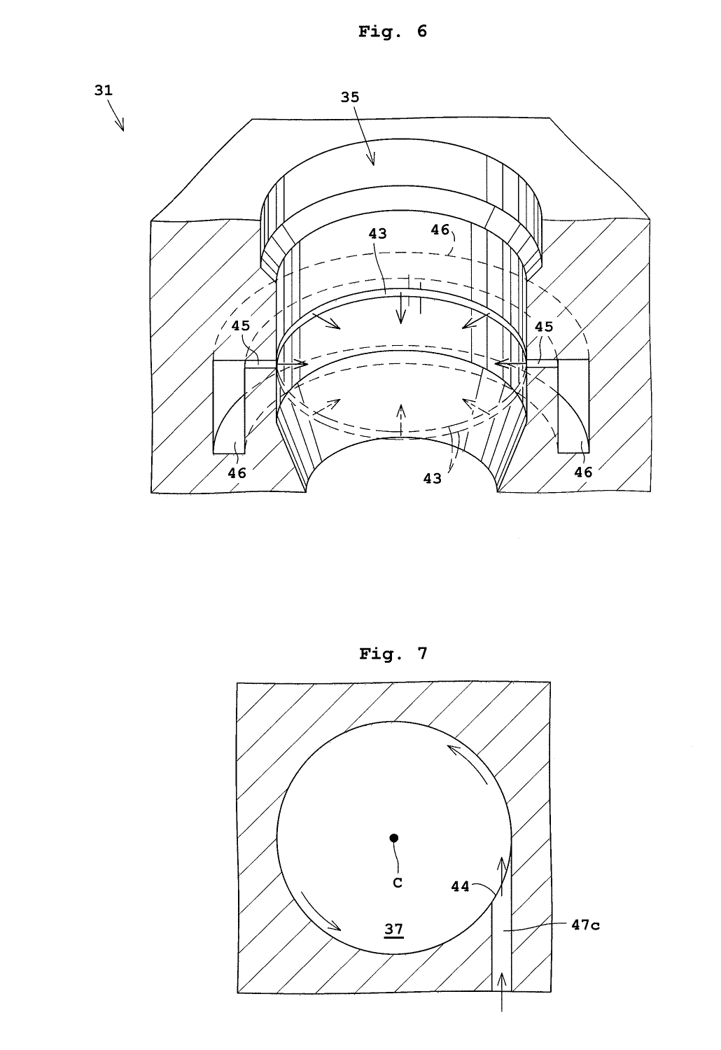

FIG. 6 is a view in vertical section of the nozzle receiving portion 35, the first discharge opening 43 and a cylindrical flow path 46 seen from an obliquely upward direction. The first discharge opening 43 is in the form of a ring-shaped slit directed inward. Consequently, the solvent can be supplied evenly toward the entire circumference of the nozzle 3 placed in the nozzle receiving portion 35.

The first feed section 41 includes a ring-shaped flat horizontal flow path 45, and the cylindrical flow path (or ring-shaped flow path) 46. An opening at the inner circumference end of the horizontal flow path 45 acts as the first discharge opening 43. The cylindrical flow path 46 communicates with an outer circumference of the horizontal flow path 45.

In the horizontal flow path 45, the nozzle cleaning liquid flows from the outer circumference end toward the first discharge opening 43 at the inner circumference end, that is along radial directions of the ring-shaped horizontal flow path 45. At this time, since the horizontal flow path 45 is a ring-shaped flat flow path, the horizontal flow path 45 is contracted progressively from the cylindrical flow path 46 at the outer circumference end toward the first discharge opening 43 at the inner circumference end. That is, the horizontal flow path 45 is contracted since a vertical sectional area taken in a ring shape (or a cylindrical shape) is smaller at the inner circumference side than at the outer circumference side of the horizontal flow path 45. Consequently, it becomes difficult for the nozzle cleaning liquid to flow toward the first discharge opening 43, and thus the nozzle cleaning liquid flows round in the circumferential direction along the horizontal flow path 45. The solvent can therefore be supplied evenly from the first discharge opening 43 toward the nozzle 3. Since the first discharge opening 43 is slit-shaped, the solvent can be supplied with vigor to the nozzle 3.

The horizontal flow path 45 communicates with an outlet (communication portion) inside an upper part of the cylindrical flow path 46. The cylindrical flow path 46 is formed to allow the solvent to flow in from under the portion of communication with the horizontal flow path 45. When the solvent flows into the cylindrical flow path 46, the solvent flows to fill the cylindrical flow path 46 from below upward. The solvent, while flowing from below upward, flows round also in the circumferential direction along the cylindrical shape. The solvent can therefore be sent evenly to the horizontal flow path 45. Consequently, the solvent can be supplied further evenly from the first discharge opening 43 toward the outer circumferential surface of the nozzle 3. The cylindrical flow path 46 causes the solvent to flow from below upward in this embodiment, but this flow path 46 may be a ring-shaped flow path, like the horizontal flow path 45, for causing the solvent to flow horizontally from the outer circumference end toward the first discharge opening 43 at the inner circumference end. The flow path (sectional area of the flow path) at an inlet (communication portion) of the horizontal flow path 45 may be contracted relative to the cylindrical flow path 46. And the flow path may be further contracted by the horizontal flow path 45.

FIG. 7 is a cross section showing the drain flow path 37 and second discharge opening 44. As shown in FIG. 7, the second discharge opening 44 is formed to face away from the central axis C of the substantially circular cross section of the drain flow path 37. For example, the second discharge opening 44 is directed away from the central axis C of the drain flow path 37 to face a direction tangent to the substantially circular cross section of the drain flow path 37. In the view in vertical section of FIG. 5, the second discharge opening 44 is formed to face a substantially horizontal direction.

As shown in FIG. 7, the second feed section 42 feeds the solvent from the second discharge opening 44 into the drain flow path 37, away from the central axis C of the drain flow path 37. Consequently, as indicated by the arrows in FIG. 7, the solvent flows to whirl around along the side surface of the drain flow path 37. In the construction shown in FIG. 7 the solvent is made to flow counterclockwise, but it may be made to flow clockwise.

Returning to FIG. 5, the solvent is sent to the first discharge opening 43 and second discharge opening 44 through solvent flow paths 47 (47a, 47b, 47c) and a common flow path 49. A switch valve 51 is disposed in an intermediate position of the solvent flow paths 47 for opening and closing the solvent flow paths 47. The common flow path 49, in the case where a plurality of standby pots 31 are provided, is a flow path shared by the standby pots 31. The solvent flow path 47a branches into two solvent flow paths 47b and 47c. The solvent flow path 47b is connected to the cylindrical flow path 46 short of the first discharge opening 43. The solvent flow path 47b may further branch to be connected to the cylindrical flow path 46. Consequently, the solvent can be supplied still more evenly from the first discharge opening 43 in the form of a ring-shaped slit. On the other hand, the solvent flow path 47c is connected to the second discharge opening 44.

The first feed section 41 includes the first discharge opening 43, horizontal flow path 45, cylindrical flow path 46, solvent flow paths 47a and 47b, common flow path 49 and switch valve 51. On the other hand, the second feed section 42 includes the second discharge opening 44, solvent flow paths 47a and 47c, common flow path 49 and switch valve 51. The first feed section 41 and second feed section 42 share the solvent flow path 47a, common flow path 49 and switch valve 51. The solvent flow paths 47 correspond to the cleaning fluid flow path in this invention.

Next, constructions of the switch valve 51 and adjacent components will be described with reference to FIG. 5. The first feed section 41 and second feed section 42 of the standby pot 31 include the solvent flow paths 47a and 47b for sending the solvent to the first discharge opening 43, the solvent flow paths 47a and 47c for sending the solvent to the second discharge opening 44, and the switch valve 51 for opening and closing the solvent flow paths 47 with a valving element 53 which takes opening and closing action. In this embodiment, the opening and closing operations cause supplying and stopping of the solvent by the first feed section 41 and second feed section 42 in common.

Further, in this embodiment, a hole 55 is interposed between the solvent flow paths 47a, 47b and 47c (between the solvent flow path 47a and the two solvent flow paths 47b and 47c) to communicate with the solvent flow paths 47a, 47b and 47c. In the hole 55, a valve seat 57 is provided for receiving the valving element 53 to shut off the solvent flow paths 47a, 47b and 47c with the valving element 53, and the switch valve 51 is disposed to have the valving element 53 movable forward and backward. The switch valve 51 cuts off circulation of the solvent by settling the valving element 53 on the valve seat 57 in the hole 55, and circulates the solvent by separating the valving element 53 from the valve seat 57 in the hole 55. Therefore, where, for example, ten standby pots 31 are arranged in a row, the above construction is made more compact than an ordinary switch valve having a valving element and a valve seat.

Since the hole 55 is closed by the switch valve 51, the solvent does not leak outside from the hole 55. In FIG. 5, the valve seat 57 is formed on the same surface of the hole 55 in which an inflow opening 59 is formed to communicate with the solvent flow path 47a. The inflow opening 59 of the solvent flow path 47a and the valve seat 57 are arranged opposite the valving element 53. The valving element 53, by moving transversely in FIG. 5, blocks off and allows circulation between the solvent flow path 47a and two solvent flow paths 47b and 47c.

FIG. 8 is a view showing a supply system for supplying the solvent to the standby pots 31. The switch valve 51 is provided for each of the ten (plurality of) standby pots 31. Consequently, the solvent can be supplied only to a necessary standby pot 31. Therefore, unlike the case of supplying the solvent to all the ten standby pots at the same time as done conventionally, it is not necessary to provide complicated flow paths in order to supply the solvent evenly to each standby pot. Further, consumption of the solvent can be inhibited compared with the prior art.

In FIG. 8, the solvent is supplied to the common flow path 49 of the standby pots 31 through solvent piping 63 from a solvent supply source 61. The solvent piping 63 has a pump P2 and a switch valve V2 arranged thereon. Although the switch valve V2 is operable to supply and stop supply of the solvent, it can also adjust the flow rate. The pump P2 feeds the solvent to the common flow path 49 of the standby pots 31. The switch valves 51, V1 and V2 are driven by air, solenoids, or motors. In FIG. 8, although the switch valves 51 and V2 are switch valves of the normally closed type, they may be switch valves of other types such as the normally open type, for example.

Returning to FIG. 3, the coating apparatus 1 includes a controller 71 constructed of a central processing unit (CPU) and others, and an operating unit 73 for operating the coating apparatus 1. The controller 71 controls each component of the coating apparatus 1. The operating unit 73 has a display such as an LCD monitor, storage media such as a ROM (Read-only Memory), a RAM (Random-Access Memory) and a hard disk, and input devices such as a keyboard, a mouse and various buttons. The storage media store various conditions for coating treatment, and other information.

The controller 71 performs the following controls, for example. The controller 71, in the state of the nozzle 3 placed in the nozzle receiving portion 35, causes the nozzle 3 to dispense the coating solution, and causes the solvent supplied to the nozzle receiving portion 35 to be sucked into the tip of the nozzle 3. Further, the controller 71 causes the solvent to be supplied from the first discharge opening 43 while causing the solvent to be supplied from the second discharge opening 44. The controller 71 also controls the pump P2, switch valve V2, and switch valve 51 of each standby pot 31.

As shown in FIG. 5, the standby pot 31 is constructed by making a fixed shape in one or more blocks. In this embodiment, the standby pot 31 is formed of three blocks (i.e. a body block 81, a spacer block 83, and a placement block 85). The body block 81 has formed therein the nozzle receiving portion 35, drain flow path 37, waste liquid collecting portion 39, first discharge opening 43, second discharge opening 44, horizontal flow path 45, cylindrical flow path 46, solvent flow paths 47, common flow path 49, hole 55 and valve seat 57. The spacer block 83 has the nozzle receiving portion 35, first discharge opening 43, horizontal flow path 45 and cylindrical flow path 46 formed therein. The placement block 85 has the nozzle receiving portion 35 formed therein. For example, the first discharge opening 43 in the form of a ring-shaped slit is constructed by combining the body block 81 and spacer block 83. The body block 81 may be divided into a plurality of parts.

The solvent flow paths 47 are formed in the same body block 81 in which the nozzle receiving portion 35 is formed. As described above, the solvent flow paths 47 have the hole 55 interposed in between and in communication therewith. The valve seat 57 is formed in the hole 55 for shutting off the solvent flow paths 47 with the valving element 53. The body block 81 corresponds to the block in this invention.

<Operation of Coating Apparatus 1>

Next, operation of the coating apparatus 1 will be described. First, operation for dispensing the coating solution from the nozzle 3 will be described.

As shown in FIG. 4, a holding and spinning unit 2A holds a wafer WA. The ten nozzles 3 stand by in the ten standby pots 31. The nozzle moving mechanism 5 selects and grips one arbitrary nozzle 3 among the ten nozzles 3. The gripped nozzle 3 is moved by the nozzle moving mechanism 5 vertically (in Z-direction) and horizontally (in XY directions) from the standby pot 31 to the position above the wafer WA, for example.

The coating solution is dispensed from the nozzle 3 onto the wafer WA on the coating conditions set beforehand. The holding and spinning unit 2 spins the wafer WA at predetermined timing and spinning speed. The pump P1 is in operation in FIG. 3. The controller 71 dispenses the coating solution from the nozzle 3 onto the wafer WA by pushing out the coating solution sucked into the tip of the nozzle 3 with the suckback valve SV while keeping the switch valve V1 in the open state. When stopping the dispensation of the treating liquid, the controller 71 causes the coating solution inside the tip of the nozzle 3 to be sucked with the suckback valve SV while keeping the switch valve V1 in the closed state.

After the dispensation of the coating solution, the nozzle moving mechanism 5 moves the nozzle 3 from above the wafer WA to a position above a wafer WB to be coated next. At the time of this movement of the nozzle 3, such as when replacing it with a different nozzle 3, movement may be made to the position above the wafer WB by way of the standby pot 31. The wafer WA onto which the coating solution has been dispensed is transported to an apparatus for a next step, and a wafer W to be treated is transported as a replacement. Before moving the nozzle 3 from the wafer WA to the position above the wafer WB, a wafer W2 to be treated is transported to a holding and spinning unit 2B. The dispensation of the coating solution to the wafers W is alternately carried out between the two holding and spinning units 2A and 2B.

Next, operation of the standby pot 31 while the nozzle 3 is standing by therein will be described. Reference is made to FIG. 5.

Each nozzle 3 which does not carry out coating treatment stands by in the standby pot 31. The nozzle 3 standing by in the standby pot 31 periodically undergoes the dummy dispensation in order to prevent drying solidification of the coating solution remaining in the nozzle 3. However, a large number of times of dummy dispensation will waste the coating solution. Therefore, the drying solidification of the coating solution in the nozzle is prevented and the number of times of dummy dispensation is reduced by sucking the solvent into the tip of the nozzle 3 and covering the tip of the nozzle 3 with the solvent.

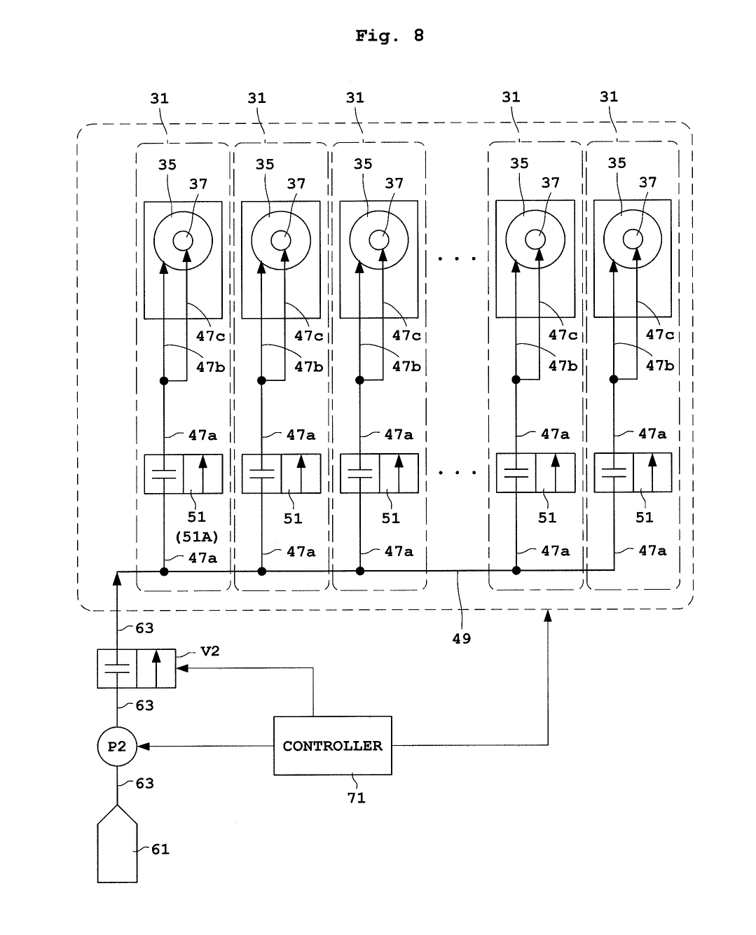

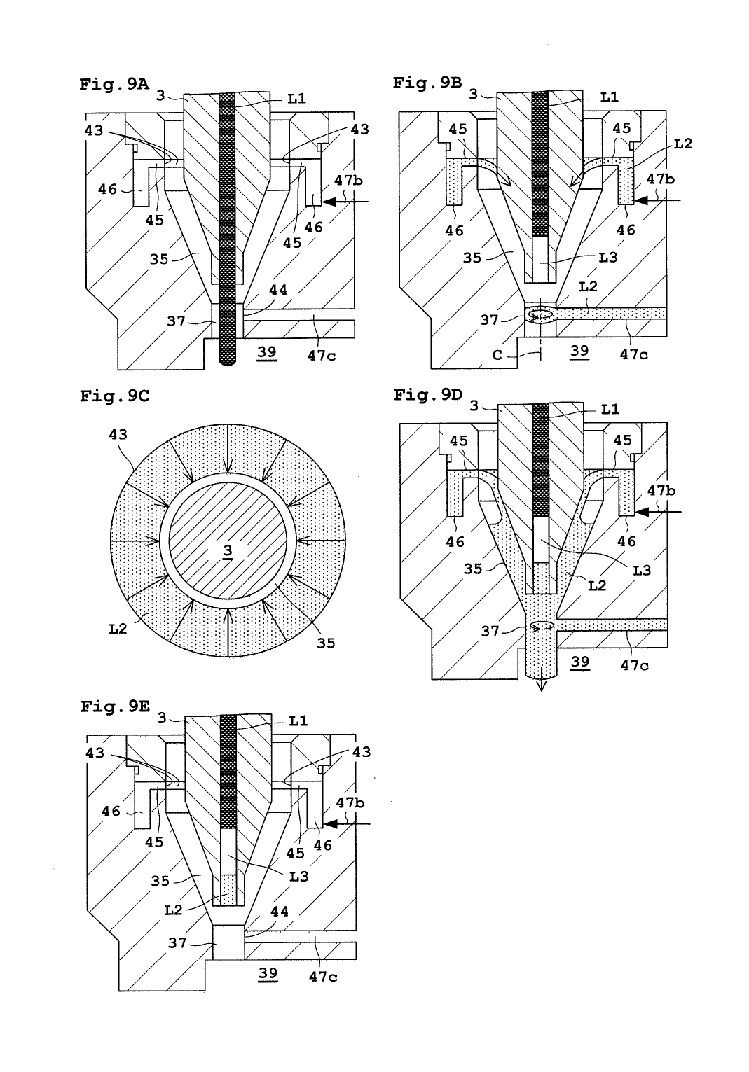

When carrying out the dummy dispensation, the controller 71 dispenses the coating solution from the nozzle 3 placed in the nozzle receiving portion 35. As shown in FIG. 9A, the dispensed coating solution passes through the drain flow path 37 to be collected in the waste liquid collecting section 39.

On the other hand, when making the nozzle 3 suck in the solvent, the controller 71 supplies the solvent from the first discharge opening 43 while discharging the solvent from the second discharge opening 44. In FIG. 8, the pump P2 is in operation, and the switch valve V2 puts the solvent piping 63 in the open state to send the solvent to the common flow path 49 of the standby pots 31. Each of the ten standby pots 31 has the switch valve 51. Of the ten switch valves 51 in the closed state, the left end switch valve 51A, for example, is opened.

When the switch valve 51A (sign 51 in FIG. 5) is opened, as shown in FIG. 5, the solvent is sent through the common flow path 49 and solvent flow path 47a, branching from the hole 55 into the two solvent flow paths 47b and 47c, and to both the nozzle receiving portion 35 and drain flow path 37.

The solvent in the solvent flow path 47b is sent to the cylindrical flow path 46, and is further sent successively to the horizontal flow path 45 and first discharge opening 43. As shown in FIGS. 5 and 6, the horizontal flow path 45 is a ring-shaped flat flow path, and is contracted progressively from the outer circumferential end toward the first discharge opening 43 at the inner circumference end. This makes it difficult for the solvent to flow to the first discharge opening 43, which causes the solvent to flow around in the circumferential direction along the horizontal flow path 45. Consequently, the solvent can be supplied evenly from the first discharge opening 43 toward the outer circumferential surface of the nozzle 3.

The cylindrical flow path 46 receives the solvent flowing in from below the communication portion with the horizontal flow path 45. The solvent flows to fill the cylindrical flow path 46 from below upward. While flowing from below upward, the solvent also moves around in the circumferential direction along the cylindrical flow path 46. The solvent can therefore be sent evenly toward the horizontal flow path 45. Consequently, the solvent can be supplied further evenly from the first discharge opening 43 toward the outer circumferential surface of the nozzle 3.

The first discharge opening 43, since it is in the form of a ring-shaped slit, can supply the solvent evenly toward the entire circumference of the nozzle 3 as shown in FIGS. 9B and 9C, thereby to reduce cleaning omissions.

On the other hand, the solvent in the solvent flow path 47c is sent to the second discharge opening 44. As shown in FIG. 7, the second discharge opening 44 in the cross section of the cylindrical drain flow path 37 is formed to supply the solvent away from the central axis C of the drain flow path 37. That is, as in FIG. 7, the second discharge opening 44 is formed so that the solvent flow along the substantially circular shape of the cross section of the drain flow path 37. Consequently, the solvent flows in a whirl in the drain flow path 37.

The solvent from the second discharge opening 44 having flowed in a whirl serves as a lid (see FIG. 9B), making it difficult for the solvent supplied from the first discharge opening 43 to the nozzle receiving portion 35 to circulate to the drain flow path 37. This can reduce the amount of discharge of the solvent supplied from the first discharge opening 43 to the nozzle receiving portion 35 and flowing through the drain flow path 37. With the solvent supplied to the substantially cylindrical drain flow path 37, the solvent will not rise through the inverted cone part of the nozzle receiving portion 35. The solvent can therefore be detained in the nozzle receiving portion 35 without assuming an unstable state.

Cleaning of the nozzle 3 is carried out by supplying the solvent from the first discharge opening 43 and second discharge opening 44 for a time set beforehand. At this time, the solvent is collected in the nozzle receiving portion 35 while the solvent is drained from the nozzle receiving portion 35. After cleaning of the nozzle 3, with a fresh solvent collected, the solvent is sucked into the tip of the nozzle 3. For example, a fresh solvent may be provided as replacement while supplying the solvent. After cleaning of the nozzle 3, the solvent supply may be stopped once and part or all of the solvent may be drained, and thereafter a fresh solvent may be collected in the nozzle receiving portion 35. The following construction may be employed, for example. The position where the solvent flow path 47c communicating with the second discharge opening 44 is connected to the hole 55 is shifted further toward the backward position of the valving element 53 than the position where the solvent flow path 47b is connected to the hole 55. A construction is made in which the openings of the solvent flow paths 47b and 47c are individually opened and closed by the outer circumferential surface of the valving element 53. Specifically, when cleaning the nozzle 3, the valving element 53 is stopped in a position for opening only the solvent flow path 47b. Then, the solvent supplied from the first discharge opening 43, after cleaning the outer circumferential surface of the nozzle 3, will be smoothly drained through the drain flow path 37. Subsequently, the valving element 53 is moved further backward to open the solvent flow path 47c also. Then, the solvent is supplied from the second discharge opening 44 to the drain flow path 37, thereby to limit the drain flow rate through the drain flow path 37. As a result, a clean solvent supplied from the first discharge opening 43 is collected in the nozzle receiving portion 35.

The solvent collected in the nozzle receiving portion 35, by controlling the suckback valve SV in FIG. 3, is sucked into the tip of the nozzle 3 as shown in FIG. 9D. After the solvent is sucked in, the switch valve 51 is operated to assume a closed state. Consequently, the supply of the solvent from the first discharge opening 43 and second discharge opening 44 is stopped, and the solvent collected in the nozzle receiving portion 35 is drained through the drain flow path 37 (see FIG. 9E). In FIGS. 9A-9E, sign L1 denotes the coating solution, sign L2 denotes the solvent, and sign L3 denotes gas such as air.

According to this embodiment, the nozzle receiving portion 35, which receives the nozzle 3 through the opening 35a formed in the upper surface thereof, is formed to taper from the opening 35a toward the bottom surface. The first feed section 41 has the first discharge opening 43 formed in the side surface inside the nozzle receiving portion 35, and supplies the nozzle cleaning liquid from the first discharge opening 43. The nozzle receiving portion 35 has the cylindrical drain flow path 37 attached to the bottom surface thereof. The drain flow path 37 drains at least the coating solution dispensed from the nozzle 3 placed in the nozzle receiving portion 35. Since the drain flow path 37 has an inside diameter D1 set to be larger than the diameter D2 of the nozzle dispenser opening 3a of the nozzle 3, the coating solution dispensed from the nozzle 3 is smoothly drained from the drain flow path 37. As a result, the coating solution does not easily adhere to the nozzle receiving portion 35. On the other hand, the drain flow path 37 is provided with the second feed section 42 acting as the drain flow rate adjuster which adjusts the drain flow rate of the solvent flowing from the nozzle receiving portion 35 and passing through the drain flow path 37. With the second feed section 42 adjusting the drain flow rate when the solvent flows through the drain flow path 37, although the inside diameter D1 of the drain flow path 37 is set larger than the diameter D2 of the nozzle dispenser opening 3a, the solvent can be collected stably in the nozzle receiving portion 35, whereby the solvent can easily be sucked into the tip of the nozzle 3.

The second feed section 42 has the second discharge opening 44 formed in the side surface inside the drain flow path 37, and the solvent is supplied from the second discharge opening 44 into the drain flow path 37, away from the central axis C of the drain flow path 37. Assume, for example, that the second discharge opening 44 is formed in the slope inside the nozzle receiving portion 35 formed to taper from the opening 35a in the upper surface toward the bottom surface. In this case, the solvent flows in a whirl upward along the slope, whereby the solvent can overflow the nozzle receiving portion 35 to become unable to be collected stably in the nozzle receiving portion 35. Since the second feed section 42 supplies the solvent from the second discharge opening 44, away from the central axis C of the cylindrical drain flow path 37, the solvent flows in a whirl in the drain flow path 37. However, since the drain flow path 37 is cylindrical, the solvent will not rise along its inner surface. The whirling flow of the solvent formed in the drain flow path 37 restricts the flow through the drain flow path 37 of the solvent supplied from the first discharge opening 43 to the nozzle receiving portion 35. As a result, the solvent supplied from the first discharge opening 43 to the nozzle receiving portion 35 can be stored stably in the nozzle receiving portion 35.

In the standby pot 31, the first feed section 41 further includes the solvent flow paths 47 for sending the solvent to the first discharge opening 43, the solvent flow paths 47 being formed in the same body block 81 in which the nozzle receiving portion 35 is formed, and the switch valve 51 for opening and closing the solvent flow paths 47 with the valving element 53 which carries out opening and closing operations. The hole 55 is interposed between the solvent flow paths 47a, 47b and 47c (between the solvent flow path 47a and the two solvent flow paths 47b and 47c) to communicate with the solvent flow paths 47a, 47b and 47c. The hole 55 has the valve seat 57 formed therein for receiving the valving element 53 to shut off the solvent flow paths 47a, 47b and 47c with the valving element 53, and accommodates the switch valve 51 in a way to enable the valving element 53 to move backward and forward. The switch valve 51 cuts off circulation of the solvent by settling the valving element 53 on the valve seat 57 in the hole 55, and circulates the solvent by separating the valving element 53 from the valve seat 57 in the hole 55.

The hole 55 interposed between the solvent flow paths 47a, 47b and 47c has the valve seat 57 formed therein and accommodates the switch valve 51. The valve seat 57 is a component separate from the switch valve 51, and is formed in the hole 55 formed in the same body block 81 in which the nozzle receiving portion 35 is formed. Therefore, where the standby pot 31 has a plurality of nozzle receiving portions 35, the construction can be made more compact than an ordinary switch valve having a valving element and a valve seat.

In the standby pot 31, the nozzle receiving portion 35 has the lower part 35b thereof formed in the shape of an inverted cone. Assume, for example, the bottom surface in the nozzle receiving portion 35 is in the form of a concave hemisphere surface. In this case, when a resist solution remains in the hemisphere surface after cleaning of the nozzle 3, the resist solution tends to remain without being removed even if the solvent is supplied. With the lower part 35b of the nozzle receiving portion 35 formed in the shape of an inverted cone, even if it is tainted with the resist solution, the resist solution remnant can be inhibited. This facilitates maintenance of the cleanliness of the interior of the nozzle receiving portion 35.

This invention is not limited to the foregoing embodiment, but may be modified as follows:

(1) In the foregoing embodiment, when one switch valve 51 is opened, the solvent is supplied from both the first discharge opening 43 and second discharge opening 44. In this regard, where space is available in the standby port 31, for example, two switch valves 51 may be provided to supply the solvent separately.

(2) In the foregoing embodiment, the standby pot 31 has the second feed section 42 provided for the drain flow path 37 as the drain flow rate adjuster for adjusting the drain flow rate of the solvent flowing from the nozzle receiving portion 35 and passing through the drain flow path 37. For example, the drain flow rate adjuster may adjust the drain flow rate mechanically.

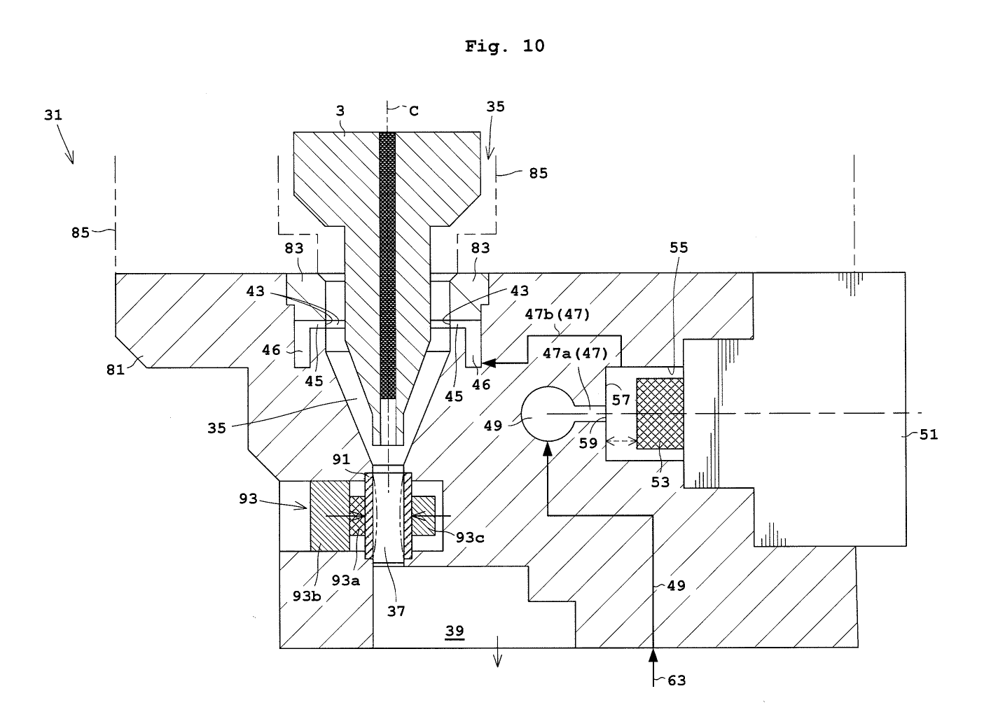

That is, the drain flow rate adjuster, as shown in FIG. 10, includes a drain pipe 91 surrounding part or all of the drain flow path 37, and a pinch valve 93 for deforming the drain pipe 91 by laterally pinching the drain pipe 91. The controller 71 in FIG. 3, when sucking the solvent into the nozzle 3, deforms the drain pipe 91 with the pinch valve 93 to reduce the drain rate of the solvent to be less than the drain rate at the time of draining the coating solution, and opens the switch valve 51 to supply the solvent from the first discharge opening 43 to the nozzle receiving portion 35.

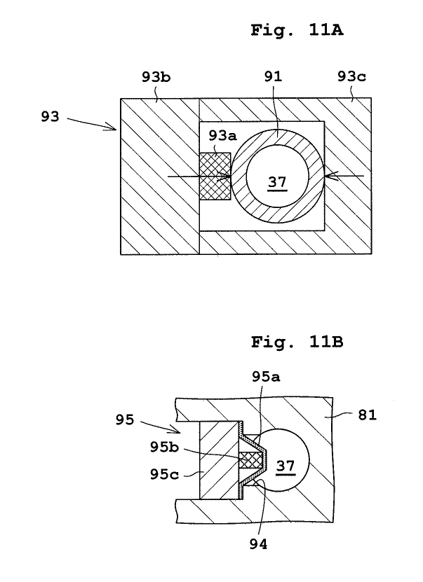

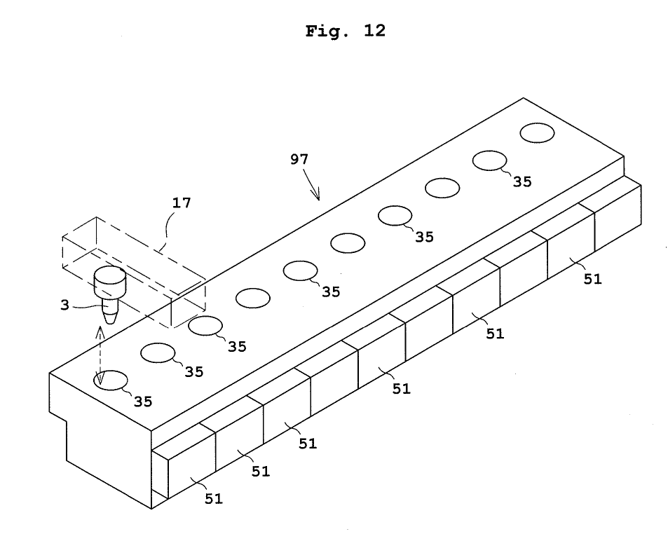

The timing of beginning to deform the drain pipe 91 with the pinch valve 93 may be the same, or approximately the same, as the timing of beginning to open the switch valve 51. The pinch valve 93, as shown in FIG. 11A, includes a movable element 93a, a driver 93b for driving the movable element 93a with air, a solenoid or a motor, and an opposite element 93c opposed to the movable element 93a. The driver 93b and opposite element 93c are connected to each other.

The pinch valve 93, in order to deform the drain pipe 91 laterally evenly, is movably mounted in the body block 81 instead of being fixed in the pinching direction. The pinching direction of the pinch valve 93 may be fixed, and the left portion of drain pipe 91 directly pushed by the movable element 93a may be deformed.

As shown in FIG. 11B, a diaphragm valve 95 may be provided in place of the drain pipe 91 and pinch valve 93. The diaphragm valve 95 is used to adjust the drain flow rate of the solvent passing through the drain flow path 37. A specific construction will be described. The drain flow path 37 is provided with a hole 94 which communicates with the drain flow path 37. The diaphragm valve 95 is disposed in the hole 94. The diaphragm valve 95 includes, for example, a diaphragm 95a for adjusting the drain flow rate, a movable element 95b for moving the diaphragm 95a to change the cross-sectional area of the drain flow path 37, and a driver 95c for driving the movable element 95b with air, a solenoid or a motor. In this case also, the controller 71 in FIG. 3 changes the cross-sectional of the drain flow path 37 with the diaphragm valve 95 to reduce the drain rate of the solvent to be less than the drain rate at the time of draining the coating solution, and opens the switch valve 51 to supply the solvent from the first discharge opening 43 to the nozzle receiving portion 35.

(3) In the foregoing embodiment and each modification, the coating apparatus 1 has a plurality of (e.g. ten) standby pots 31, but may have one standby pot 31. In this case, the standby pot 31 has one nozzle receiving portion 35. Since there is one nozzle 3, the nozzle 3 may be attached to the nozzle moving mechanism 5.

As shown in FIG. 12, one standby pot 97 may have ten nozzle receiving portions 35 in order to receive ten nozzles 3. That is, in this example, the ten standby pots 31 are integrated into one standby pot 97. In this case, each of the ten nozzle receiving portions 35 has at least the drain flow path 37, first feed section 41 and second feed section 42. The first feed section 41 and second feed section 42 include the switch valve 51.

Consequently, the plurality of nozzles 3 can be put on standby, and the above-noted effects are acquired with the plurality of nozzle receiving portions 35. For example, with the switch valve 51 provided for each of the nozzle receiving portions 35, the construction of the standby pot 97 having the switch valves 51 can be made compact. The switch valve 51 provided for each nozzle receiving portion 35 can selectively supply the solvent. Consumption of the solvent can be held down since the solvent is supplied only to the nozzle receiving portions 35 needing to be cleaned among the plurality of (ten) nozzle receiving portions 35. The complexity of the construction of the solvent flow paths 47 can also be lessened.

(4) In the foregoing embodiment and each modification, a substrate treating apparatus has been described as coating apparatus 1 which applies a coating solution to wafers W, but it may be a developing apparatus, for example. The developing apparatus has a nozzle for dispensing a developer (or rinsing liquid) to the wafers W. The developer and rinsing liquid correspond to the treating liquid in this invention. The nozzle which dispenses the developer is cleaned with a nozzle cleaning liquid in the standby pot 31, and in certain circumstances the nozzle cleaning liquid is sucked into the tip of the nozzle, whereby, as in FIG. 9E, the nozzle cleaning liquid forms a lid. Deionized water (DIW) is used as the nozzle cleaning liquid.

(5) In the foregoing embodiment and each modification, the first discharge opening 43 is in the form of a ring-shaped slit. As necessary, for example, a plurality of discharge openings may be formed in the side surface inside the nozzle receiving portion 35 to surround the nozzle 3 placed in the nozzle receiving portion 35.

(6) In the foregoing embodiment and each modification, although the first discharge opening 43 is in the form of a ring-shaped slit, it may be constructed as follows as long as the same effect is produced. For example, one ring-shaped slit may be approximately ring-shaped, i.e. C-shaped. Or two or more may form a ring.

(7) In the foregoing embodiment and each modification, one of the ten switch valves 51 in the ten (plurality of) standby pots 31 is opened. However, a plurality (including all) of the switch valves in the ten standby pots 31 may be opened at the same time as long as the feed rate of the solvent is even. The switch valve 51 may have a function to adjust the passing flow rate. This adjusting function may be performed by the operator adjusting a screw adjuster provided in the switch valve 51. The adjustment may be made with an electric signal inputted by the operator.

This invention may be embodied in other specific forms without departing from the spirit or essential attributes thereof and, accordingly, reference should be made to the appended claims, rather than to the foregoing specification, as indicating the scope of the invention.

1. A nozzle standby device for holding a nozzle on standby, comprising;
a nozzle receiving portion having an opening in an upper surface thereof for receiving the nozzle through the opening, the nozzle receiving portion being formed to taper from the opening toward a bottom surface thereof;
a cylindrical drain flow path attached to the bottom surface of the nozzle receiving portion for draining at least a treating liquid dispensed from the nozzle placed in the nozzle receiving portion, the drain flow path having an inside diameter larger than a diameter of a nozzle dispenser opening of the nozzle;
a first feed section having a first discharge opening formed in a side surface inside the nozzle receiving portion for supplying a nozzle cleaning liquid from the first discharge opening; and
a drain flow rate adjuster provided for the drain flow path for adjusting a drain flow rate of the nozzle cleaning liquid flowing from the nozzle receiving portion and passing through the drain flow path.

2. The nozzle standby device according to claim 1, wherein the drain flow rate adjuster comprises a second feed section having a second discharge opening formed in a side surface inside the drain flow path for supplying the nozzle cleaning liquid from the second discharge opening into the drain flow path to be away from a central axis of the drain flow path.

3. The nozzle standby device according to claim 1, wherein the first discharge opening is in form of a ring-shaped slit directed inward.

4. The nozzle standby device according to claim 3, wherein the first feed section has a ring-shaped flat horizontal flow path, the horizontal flow path having an opening at an inner circumference end thereof acting as the first discharge opening.

5. The nozzle standby device according to claim 1, wherein:
the first feed section further includes a cleaning liquid flow path for sending the nozzle cleaning liquid to the first discharge opening, the cleaning liquid flow path being formed in a block in which the nozzle receiving portion is formed, and a switch valve having a valving element which takes opening and closing action for opening and closing the cleaning liquid flow path;
the cleaning liquid flow path includes a hole interposed therein to communicate with the cleaning liquid flow path;
the hole includes a valve seat formed therein for shutting off the cleaning liquid flow path with the valving element, the switch valve being disposed in the hole to have the valving element movable forward and backward; and
the switch valve cuts off circulation of the cleaning liquid by settling the valving element on the valve seat in the hole, and circulating the cleaning liquid by separating the valving element from the valve seat in the hole.

6. The nozzle standby device according to claim 5, comprising a plurality of nozzle receiving portions;
wherein each of the nozzle receiving portions includes at least the drain flow path, the first feed section including the switch valve, and the drain flow rate adjuster.

7. The nozzle standby device according to claim 1, wherein the nozzle receiving portion has a lower part thereof formed in shape of an inverted cone.

8. A substrate treating apparatus comprising:
a nozzle for dispensing a treating liquid to a substrate; and
a nozzle standby device for holding the nozzle on standby;
wherein the nozzle standby device includes:
a nozzle receiving portion having an opening in an upper surface thereof for receiving the nozzle through the opening, the nozzle receiving portion being formed to taper from the opening toward a bottom surface thereof;
a cylindrical drain flow path attached to the bottom surface of the nozzle receiving portion for draining at least a treating liquid dispensed from the nozzle placed in the nozzle receiving portion, the drain flow path having an inside diameter larger than a diameter of a nozzle dispenser opening of the nozzle;
a first feed section having a first discharge opening formed in a side surface inside the nozzle receiving portion for supplying a nozzle cleaning liquid from the first discharge opening; and
a drain flow rate adjuster provided for the drain flow path for adjusting a drain flow rate of the nozzle cleaning liquid flowing from the nozzle receiving portion and passing through the drain flow path.
